(19) United States
(12) Patent Application Publication
(10) Pub. No.: US 2025/0192734 A1
(43) Pub. Date: Jun. 12, 2025

(54) MULTI-CHIP RADIO FREQUENCY CIRCUIT

(71) Applicant: RichWave Technology Corp., Taipei (TW)

(72) Inventors: Chang-Yi Chen, Taipei (TW); Chih-Sheng Chen, Taipei (TW)

(73) Assignee: RichWave Technology Corp., Taipei (TW)

(21) Appl. No.: 18/424,831

(22) Filed: Jan. 28, 2024

(30) Foreign Application Priority Data
Dec. 11, 2023 (TW) 112148169

(51) Int. Cl. H03F 3/19; H03F 1/56

(52) U.S. Cl. CPC H03F 3/19; H03F 1/56; H03F 2200/222; H03F 2200/387; H03F 2200/451

(57) ABSTRACT

A multi-chip radio frequency circuit is coupled between a first port and a second port. The first port is disposed in a first chip and the second port is disposed in a second chip. The multi-chip RF circuit includes a first amplifying circuit, a transmission circuit, and a first switch. The first amplifying circuit is disposed in the first chip and coupled to the first port. The transmission circuit is disposed in the second chip and coupled to the second port. The transmission circuit further includes at least one transmission switch. The transmission switch and a first switch are used to select one of a first path and a second path between the first port and second port. Both of the first path and the second path pass through the first chip and the second chip, and respectively pass through the transmission circuit and the first amplifying circuit.

### CROSS-REFERENCE TO RELATED APPLICATION

This application claims the priority benefit of Taiwan application serial no. 112148169, filed on Dec. 11, 2023. The entirety of the above-mentioned patent application is hereby incorporated by reference herein and made a part of this specification.

### BACKGROUND

### Technical Field

This disclosure relates to a multi-chip radio frequency circuit, and particularly relates to a multi-chip radio frequency circuit capable of switching between multiple modes.

### Description of Related Art

In order to improve working performance of a radio frequency circuit, the radio frequency circuit is often operated in different modes. In order to perform switching of these modes, in the radio frequency circuit, in addition to configuring corresponding amplifying circuits, switching elements also need to be configured to complete switching of the operating modes. In the conventional technical field, multi-mode radio frequency circuits with the amplifying circuits and the switching elements are often provided on a single chip. Considering a working performance of the amplifying circuits and the switching elements, the multi-mode radio frequency circuit is often constructed by using bipolar field effect transistor (BiFET) or bipolar complementary metal oxide semiconductor (BiCMOS) process chips. However, material cost required for the BiFET and BiCOMS process chips is high, and simultaneous arrangement of the amplifying circuits and switching elements in a single BiFET or BiCOMS process chip may increase process complexity, thereby increasing the circuit cost. In addition, there is still room for working performance improvement of the switching elements provided in the BiFET or BiCOMS process chip.

### SUMMARY

The disclosure is directed to a multi-chip radio frequency (RF) circuit, which is adapted to effectively reduce circuit cost of the radio frequency circuit and improve performance of the radio frequency circuit.

The disclosure provides a multi-chip radio frequency circuit coupled between a first port and a second port. The first port is disposed in a first chip and the second port is disposed in a second chip. The multi-chip radio frequency circuit includes a first amplifying circuit, a transmission circuit, and a first switch. The first amplifying circuit is disposed in the first chip and coupled to the first port. The transmission circuit is disposed in the second chip and coupled to the second port. The transmission circuit further includes at least one transmission switch. The first switch is coupled to the first amplifying circuit. The transmission switch and the first switch are configured to select one of a first path and a second path between the first port and second port, and both of the first path and the second path pass through the first chip and the second chip, and respectively pass through the transmission circuit and the first amplifying circuit.

Based on the above description, in the disclosure, by disposing the amplifying circuit in the first chip of the multi-chip radio frequency circuit and disposing the transmission circuit in the second chip of the multi-chip radio frequency circuit, corresponding processes may be respectively selected for the first chip and the second chip according to the circuit elements that need to be constructed. In this way, the circuit cost of the multi-chip RF circuit may be reduced, and working efficiency thereof may also be effectively improved.

### BRIEF DESCRIPTION OF THE DRAWINGS

The accompanying drawings are included to provide a further understanding of the disclosure, and are incorporated in and constitute a part of this specification. The drawings illustrate embodiments of the disclosure and, together with the description, serve to explain the principles of the disclosure.

FIG. 1 is a schematic diagram of a multi-chip radio frequency (RF) circuit according to an embodiment of the disclosure.

FIG. 2 is a schematic diagram of a multi-chip RF circuit according to another embodiment of the disclosure.

FIG. 3 is a schematic diagram of a multi-chip RF circuit according to another embodiment of the disclosure.

FIG. 4A to FIG. 4C are schematic diagrams of multiple implementations of multi-chip RF circuits according to an embodiment of the disclosure.

FIG. 5 is a schematic diagram of a multi-chip RF circuit according to another embodiment of the disclosure.

FIG. 6 is a schematic diagram of another implementation of a multi-chip RF circuit according to an embodiment of the disclosure.

### DESCRIPTION OF THE EMBODIMENTS

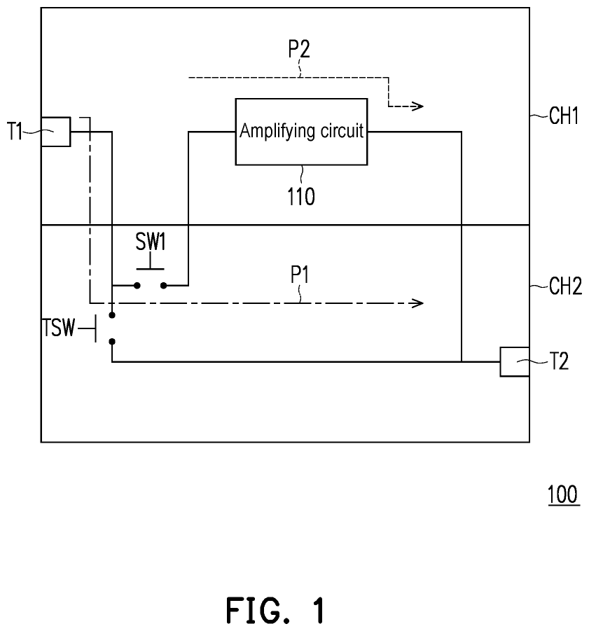

Referring to FIG. 1, FIG. 1 is a schematic diagram of a multi-chip radio frequency (RF) circuit according to an embodiment of the disclosure. A multi-chip RF circuit 100 is coupled between a first port T1 and the second port T2. In the embodiment, the first port T1 is disposed in a first chip CH1, and the second port T2 is disposed in a second chip CH2. The multi-chip RF circuit 100 includes an amplifying circuit 110, a transmission circuit 120 and a switch SW1.

In the embodiment, the amplifying circuit 110 may be disposed in the first chip CH1, and the amplifying circuit 110 is coupled to the first port T1. The transmission circuit 120 may be disposed in the second chip CH2, and the transmission circuit 120 is coupled to the second port T2, and may include a transmission switch TSW. In the embodiment, the switch SW1 is, for example, disposed in the second chip CH2. As shown in FIG. 1, the transmission switch TSW is coupled between the first port T1 and the second port T2. In the embodiment, a first terminal of the transmission switch TSW is coupled to the first port T1, a second terminal of the transmission switch TSW is coupled to the second port T2, a first terminal of the switch SW1 is coupled between the first port T1 and the transmission switch TSW, a second terminal of the switch SW1 is coupled to an input terminal of the amplifying circuit 110, and an output terminal of the amplifying circuit 110 is coupled between the second terminal of the transmission switch TSW and the second port T2.

It should be noted that in the embodiment, the multi-chip RF circuit 100 may be switched between two operating modes. Furthermore, the multi-chip RF circuit 100 may select one of a first path P1 and a second path P2 between the first port T1 and the second port T2 through the transmission switch TSW and the switch SW1, to serve as an operation of one of a first mode and a second mode. In the embodiment, when the multi-chip RF circuit 100 operates in the first mode, the switch SW1 may be turned off and the transmission switch TSW may be turned on. In this way, the first path P1 starting from the first port T1 and passing through the transmission switch TSW to reach the second port T2 may be created, and RF signals may be transmitted through the first path P1, and at the same time, the second path P2 may be turned off. Comparatively, in the second mode, the switch SW1 may be turned on, and the transmission switch TSW may be turned off. In this way, the second path P2 starting from the first port T1 and passing through the switch SW1 and the amplifying circuit 110 to reach the second port T2 may be created, and the RF signals may be transmitted through the second path P2. In the embodiment of the disclosure, in the first mode, the first path P1 bypasses the amplifying circuit 110, and is started from the first port T1 and coupled to the second port T2 through the transmission circuit 120, so that the first mode may be a low power mode. In the second mode, the second path P2 may pass through the amplifying circuit 110, and the amplifying circuit 110 may amplify a power of the RF signal, so that the second mode may be a high power mode. In this way, the first path P1 and the second path P2 both pass through the first chip CH1 and the second chip CH2, and the first path P1 and the second path P2 respectively pass through the transmission circuit 120 and the amplifying circuit 110. In the embodiment, a number of amplifiers passed by the first path P1 may be smaller than a number of amplifiers passed by the second path P2.

In the embodiment, since the amplifying circuit 110 is disposed in the first chip CH1, and the transmission switch TSW of the transmission circuit 120 is disposed in the second chip CH2, and a material of the first chip CH1 is different from a material of the second chip CH2, materials suitable for manufacturing the amplifying circuit 110 and the transmission switch TSW may be respectively selected for the first chip CH1 and the second chip CH2 for manufacturing in terms of cost and work performance. In this way, the material cost may be reduced, and the working performance of the transmission switch TSW may be improved while maintaining the working performance of the amplifying circuit 110, and complexity of the manufacturing process may be reduced to reduce the manufacturing cost. Furthermore, in the embodiment, a material of the first chip CH1 may include gallium arsenide or silicon germanium. Alternatively, the components of the first chip CH1 may include III-V semiconductors, bipolar field effect transistors (BiFET) or bipolar complementary metal oxide semiconductors (BiCMOS). The above materials or components are suitable for use in amplifier components, so that the amplifying circuit 110 has better working performance, such as high linearity, or high power added efficiency (PAE), which may save power consumption. The material of the second chip CH2 may include silicon on insulator (SOI). Alternatively, the components of the second chip CH2 may include complementary metal oxide semiconductors (CMOS) or pseudomorphic high electron mobility transistors (pHEMT). The above materials or components are suitable for use in switching elements, so that the transmission switch TSW of the transmission circuit 120 has better working performance, such as the transmission switch TSW has low insertion loss when being turned on, and has low loading when being turned off. Moreover, compared with the BiFET and the BiCMOS, the cost of SOI, CMOS and pHEMT is relatively low. All switching elements (including the switch SW1 and the transmission switch TSW) in the multi-chip RF circuit 100 may be disposed in the second chip CH2, and all amplifying circuits (including the amplifying circuit 110) used to perform signal amplification operations in the multi-chip RF circuit 100 are all arranged in the first chip CH1. In this way, the complexity of the manufacturing process and the material cost may be further reduced, and the working performance of the switch SW1 may also be improved. In other embodiments, since the BiFET and the BiCMOS are also suitable for use in the switching elements, for example, in the case where the first chip CH1 uses a BiFET or a BiCMOS, the switch that is configured closer to the amplifying circuit 110, such as the switch SW1, may also be disposed in the first chip CH1, thereby improving the working performance of the switch SW1, while other switches (such as the transmission switch TSW) may remain being disposed in the second chip CH2 to reduce some material cost.

In addition, multiple first bonding pads (not shown) may be formed on the first chip CH1. The first port T1 in the first chip CH1 and the output terminal and the input terminal of the amplifying circuit 110 may be respectively coupled to the first pads on the first chip CH1. Multiple second bonding pads (not shown) may be formed on the second chip CH2. The first terminal of the switch SW1, the first terminal of the transmission switch TSW, the second terminal of the switch SW1, and the second port T2 in the second chip CH2 may be respectively coupled to the second bonding pads. The first bonding pads may be respectively coupled to the corresponding second bonding pads through bonding wires, or the first bonding pads may be respectively coupled to the corresponding second bonding pads through flip chip package. Furthermore, through the above bonding wires or flip-chip package, the first port T1 may be coupled to the first terminal of the switch SW1 and the first terminal of the transmission switch TSW; the input terminal of the amplifying circuit 110 may be coupled to the second terminal of the switch SW1; and the output terminal of the amplifying circuit 110 may be coupled to the second port T2, thereby forming the multi-chip RF circuit 100.

In the embodiment, the first port T1 may be coupled to a signal transmitting terminal, and the second port T2 may be coupled to an antenna terminal.

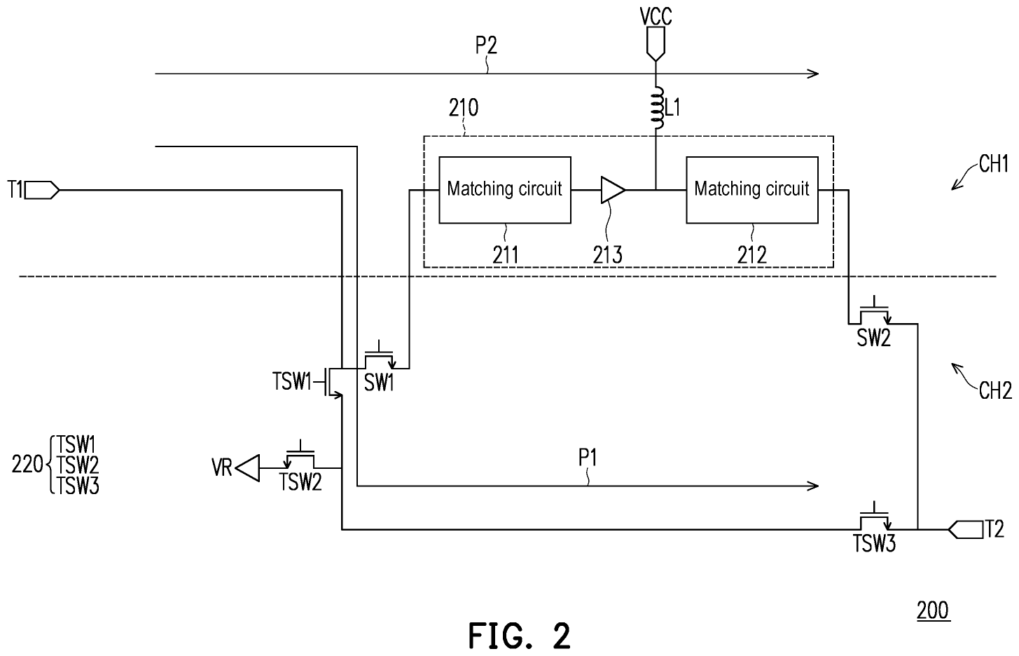

Referring to FIG. 2, FIG. 2 is a schematic diagram of a multi-chip RF circuit according to another embodiment of the disclosure. A multi-chip RF circuit 200 includes an amplifying circuit 210, a transmission circuit 220, and switches SW1 and SW2. The amplifying circuit 210 includes matching circuits 211, 212 and an amplifier 213, and the switch SW1 is coupled between the first port T1 and the amplifier 213. Furthermore, in the embodiment, the matching circuit 211 is coupled between the first port T1 and an input terminal of the amplifier 213, and the matching circuit 212 is coupled between an output terminal of the amplifier 213 and the second port T2, and a second terminal of the switch SW1 is coupled to an input terminal of the matching circuit 211 of the amplifying circuit 210. The output terminal of the amplifier 213 may be pulled up to a reference voltage VCC through an inductor L1. The transmission circuit 220 includes transmission switches TSW1, TSW2, and TSW3. A first terminal of the transmission switch TSW1 is coupled between the first port T1 and the switch SW1, and a second terminal of the transmission switch TSW1 is coupled to the second port T2 through the transmission switch TSW3. A first terminal of the transmission switch TSW2 is coupled between the transmission switch TSW1 and the transmission switch TSW3, and a second terminal of the transmission switch TSW2 is coupled to a reference voltage terminal VR. The transmission switch TSW3 is coupled between the transmission switch TSW1 and the second port T2. In addition, the switch SW2 is coupled between the amplifying circuit 210 and the second port T2. Furthermore, a first terminal of the switch SW2 is coupled to an output terminal of the matching circuit 212, and a second terminal of the switch SW2 is coupled between the transmission switch TSW3 and the second port T2.

Similar to the embodiment of FIG. 1, in the embodiment, the first port T1 and the amplifying circuit 210 are disposed in the first chip CH1, and the switches SW1, SW2, the transmission switches TSW1, TSW2, TSW3 and the second port T2 are all disposed in the second chip CH2.

Regarding the operation details, when the multi-chip RF circuit 200 operates in the high power mode, the switches SW1 and SW2 and the transmission switch TSW2 are turned on, and the transmission switches TSW1 and TSW3 are turned off. An RF signal received by the first port T1 may be transmitted to the second port T2 via the second path P2, through the switch SW1, the amplifying circuit 210 and the switch SW2. When the multi-chip RF circuit 200 operates in the low power mode, the switches SW1 and SW2 and the transmission switch TSW2 are turned off, and the transmission switches TSW1 and TSW3 are turned on. The RF signal received by the first port T1 may be transmitted to the second port T2 via the first path P1 through the transmission switch TSW1 and the transmission switch TSW3.

In addition, in the embodiment of the disclosure, the switches SW1, SW2 and the transmission switches TSW1, TSW2, and TSW3 may all be transistor switches, and may all be disposed in the second chip CH2. The amplifier 213 may be any form of amplifier and is disposed in the first chip CH1. In this way, the material cost may be reduced, the working performance of the transmission switches TSW1, TSW2, and TSW3 may be improved while maintaining the working performance of the amplifier 213, and the complexity of the manufacturing process may be reduced to reduce the process cost. In other embodiments, since the BiFET and the BiCMOS are also suitable for use in switching elements, for example, in the case where the first chip CH1 uses a BiFET or a BiCMOS, the switches SW1 and SW2 that are arranged closer to the amplifying circuit 210 may also be disposed in the first chip CH1, thereby improving the working performance of the switches SW1 and SW2, while the transmission switches TSW1, TSW2 and TSW3 may remain being disposed in the second chip CH2 to reduce some material cost.

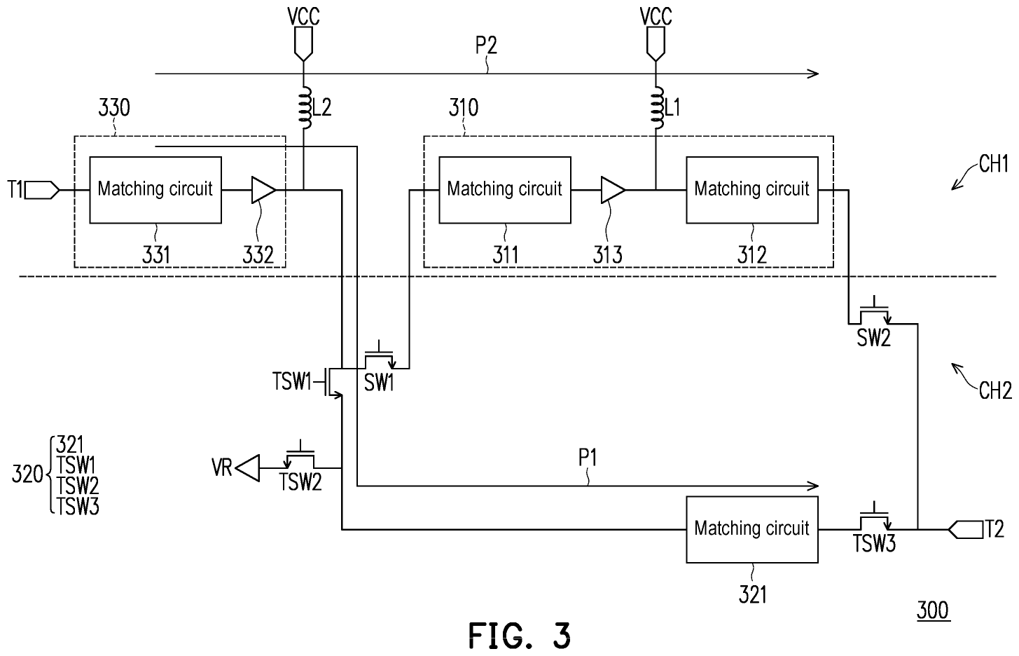

Referring to FIG. 3, FIG. 3 is a schematic diagram of a multi-chip RF circuit according to another embodiment of the disclosure. A multi-chip RF circuit 300 includes amplifying circuits 310 and 330, a transmission circuit 320 and switches SW1 and SW2. The amplifying circuits 310 and 330 and the first port T1 are disposed in the first chip CH1. The amplifying circuit 330 is coupled to the first port T1 to receive the RF signal, and the amplifying circuit 330 is coupled between the first port T1 and the amplifying circuit 310. The amplifying circuit 310 includes an amplifier 313, and the amplifying circuit 330 includes an amplifier 332. The switch SW1 is coupled between the first port T1 and the amplifier 313, the amplifier 332 is coupled between the first port T1 and the amplifier 313, and the switch SW1 is coupled between the amplifier 332 and the amplifier 313. Further, the amplifier 332 is coupled to a first terminal of the switch SW1 and a first terminal of the transmission switch TSW1. In addition, the amplifying circuit 310 further includes matching circuits 311 and 312. The amplifying circuit 330 further includes a matching circuit 331, where the matching circuit 311 is coupled between an input terminal of the amplifier 313 and the switch SW1. The matching circuit 312 is coupled between an output terminal of the amplifier 313 and the switch SW2, and the matching circuit 331 is coupled between the first port T1 and an input terminal of the amplifier 332. In the embodiment, the amplifier 332 is, for example, a first-stage amplifier, the amplifier 313 is, for example, a second-stage amplifier, the matching circuit 311 is, for example, an inter-stage matching circuit, the matching circuit 312 is, for example, an output matching circuit, and the matching circuit 331 is an input matching circuit. In addition, the output terminal of the amplifier 332 is pulled up to the reference voltage VCC through an inductor L2. The output terminal of the amplifier 313 is pulled up to the reference voltage VCC through an inductor L1.

The transmission circuit 320 includes transmission switches TSW1, TSW2, TSW3 and a matching circuit 321, and is disposed in the second chip CH2 together with the second port T2. Where, the transmission switch TSW1, the matching circuit 321 and the transmission switch TSW3 are coupled in series between the output terminal of the amplifier 332 and the second port T2. The first terminal of the transmission switch TSW1 is coupled between the output terminal of the amplifier 332 and the switch SW1, and the second terminal of the transmission switch TSW1 is coupled to the second port T2 through the matching circuit 321 and the transmission switch TSW3. The first terminal of the transmission switch TSW2 is coupled between the transmission switch TSW1 and the matching circuit 321, and the second terminal of the transmission switch TSW2 is coupled to the reference voltage terminal VR. The transmission switch TSW3 is coupled between the output terminal of the matching circuit 321 and the second port T2. In addition, the switch SW2 is coupled between the amplifying circuit 310 and the second port T2. Furthermore, the first terminal of the switch SW2 is coupled to the output terminal of the matching circuit 312, and the second terminal of the switch SW2 is coupled to the transmission switch TSW3 and the second port T2. In the embodiment, the switches SW1 and SW2 may be disposed in the second chip CH2; in other embodiments, for example, when the first chip CH1 adopts a BiFET or a BiCMOS, the switches SW1 and SW2 may also be disposed in the first chip CH1.

Regarding operation details, when the multi-chip RF circuit 300 operates in the high power mode, the switches SW1 and SW2 and the transmission switch TSW2 are turned on, and the transmission switches TSW1 and TSW3 are turned off. The RF signal received by the first port T1 may be transmitted to the second port T2 via the second path P2 through the amplifying circuit 330, the switch SW1, the amplifying circuit 310 and the switch SW2. When the multi-chip RF circuit 300 operates in the low power mode, the switches SW1 and SW2 and the transmission switch TSW2 are turned off, and the transmission switches TSW1 and TSW3 are turned on. The RF signal received by the first port T1 may be transmitted to the second port T2 via the first path P1 through the amplifying circuit 330 (but not through the amplifying circuit 310), the transmission switch TSW1, the matching circuit 321 and the transmission switch TSW3.

From the above description, it is easy to know that in the high power mode, the RF signal is subjected to two-stage amplifying effects of the amplifiers 332 and 313 and then transmitted to the second port T2. In contrast, in the low power mode, the RF signal is only subjected to one-stage amplifying effect of the amplifier 332 and then transmitted to the second port T2.

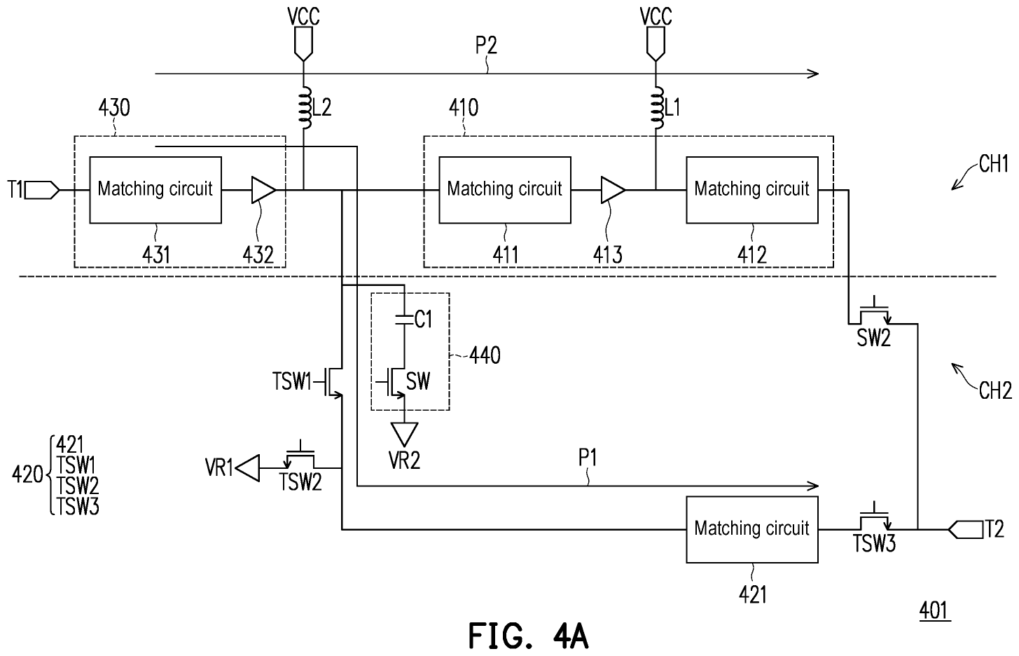

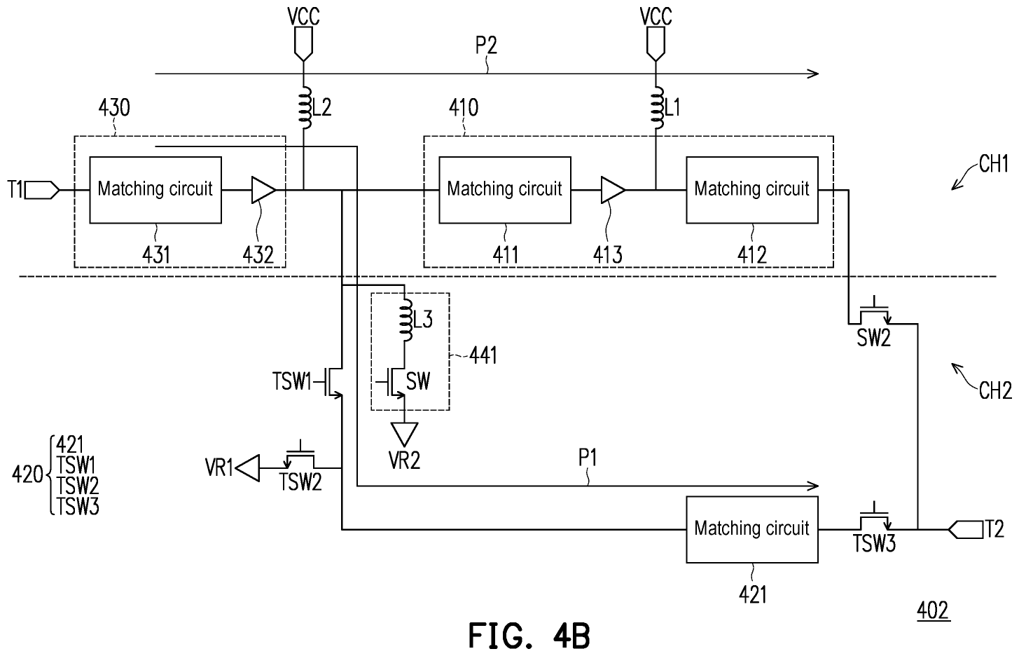

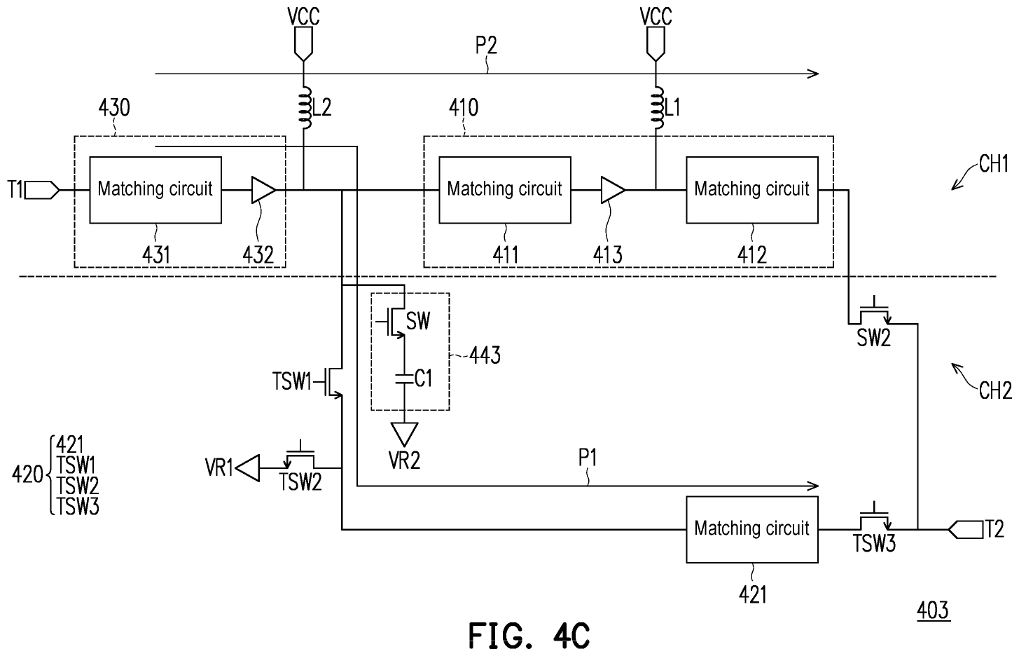

Referring to FIG. 4A to FIG. 4C, FIG. 4A to FIG. 4C are schematic diagrams of multiple implementations of multi-chip RF circuits according to an embodiment of the disclosure. In FIG. 4A, a multi-chip RF circuit 401 includes amplifying circuits 410 and 430, a transmission circuit 420 and a switch SW2. In the embodiment, the amplifying circuits 410 and 430 and the first port T1 are disposed in the first chip CH1. The amplifying circuit 430 is coupled to the first port T1 to receive a RF signal, and the amplifying circuit 430 is coupled between the first port T1 and the amplifying circuit 410. The amplifying circuit 410 includes an amplifier 413, and the amplifying circuit 430 includes an amplifier 432. In addition, the amplifying circuit 410 further includes matching circuits 411 and 412. The amplifying circuit 430 further includes a matching circuit 431. Furthermore, the matching circuit 411 is coupled between the first port T1 and an input terminal of the amplifier 413, and coupled between the amplifier 432 and the amplifier 413. The matching circuit 412 is coupled between an output terminal of the amplifier 413 and the switch SW2, and the matching circuit 431 is coupled between the first port T1 and an input terminal of the amplifier 432. In the embodiment, the amplifier 432 is, for example, a first-stage amplifier, the amplifier 413 is, for example, a second-stage amplifier, the matching circuit 411 is, for example, an inter-stage matching circuit, the matching circuit 412 is, for example, an output matching circuit, and the matching circuit 431 is an input matching circuit.

In the embodiment, the transmission circuit 420, the switch SW2 and the second port T2 are all disposed in the second chip CH2. In other embodiments, for example, when the first chip CH1 adopts a BiFET or a BiCMOS, the switch SW2 may also be disposed in the first chip CH1. The transmission circuit 420 includes transmission switches TSW1, TSW2, TSW3 and a matching circuit 421.

Different from the embodiment of FIG. 3, the multi-chip RF circuit 401 is further provided with a shunt circuit 440 and does not have the switch SW1 of the embodiment of FIG. 3. A first terminal of the shunt circuit 440 is coupled to the amplifying circuit 410, and a second terminal of the shunt circuit 440 is coupled to a reference voltage terminal VR2. Furthermore, the first terminal of the shunt circuit 440 is coupled between the first port T1 and the matching circuit 411, and the first terminal of the shunt circuit 440 is coupled between an output terminal of the amplifier 432 and a first terminal of the transmission switch TSW1. The first terminal of the transmission switch TSW1 is coupled between the output terminal of the amplifier 432 and the first terminal of the shunt circuit 440. A second terminal of the transmission switch TSW1 is coupled to the second port T2 through the matching circuit 421 and the transmission switch TSW3. The shunt circuit 440 includes a reactance element and a switch SW, where the reactance element is, for example, a capacitor C1. In the present implementation, the capacitor C1 is coupled between the output terminal of the amplifier 432 and the switch SW, and the switch SW is coupled between the capacitor C1 and the reference voltage terminal VR2.

In the low power mode, i.e., the first path P1 is selected, the transmission switches TSW1, TSW3 and the switch SW are all turned on, the transmission switch TSW2 and the switch SW2 may be turned off, in this way, the first path P1 may be established. Where, when the switch SW is turned on, the matching circuit 411 and the reactance element (the capacitor C1) may provide a high impedance. Furthermore, based on the output terminal of the amplifier 432, the matching circuit 411 has an input impedance (inductive impedance) of +jx, and the capacitor C1 of the shunt circuit 440 may provide an input impedance (capacitive impedance) of −jx, where x is any real number. At this time, based on a frequency of the RF signal generated by the amplifier 432, through a resonance effect produced by connecting the inductive impedance and the capacitive impedance in parallel with each other, a relatively high impedance may be generated at an input terminal of the matching circuit 411 to cut off the second path P2.

In the high power mode, i.e., the second path P2 is selected, the transmission switches TSW1, TSW3 and the switch SW are all turned off, and the transmission switches TSW2 and the switch SW2 may be turned on. At this time, the shunt circuit 440 is inactive, the second path P2 may be established, and the first path P1 may be cut off. Furthermore, in the embodiment of FIG. 4A, the shunt circuit 440 is adopted to replace the switch SW1 of the embodiment of FIG. 3, and when the second path P2 (the high power mode) is selected, the switch SW in the shunt circuit 440 is turned off; and in the aforementioned embodiment of FIG. 3, when the second path P2 (the high power mode) is selected, the switch SW1 is turned on. In this way, compared with the embodiment of FIG. 3, the embodiment of FIG. 4A requires fewer switching elements to be turned on when the second path P2 (the high power mode) is selected, thereby reducing the insertion loss caused by turning on of the switching elements. Moreover, in the embodiment of FIG. 3, the first terminal and the second terminal of the switch SW1 are coupled to the first chip CH1. If bonding wires are used to connect the first chip CH1 and the second chip CH2, two bonding wires need to be used for the above connection. However, if the coupling method of the shunt circuit 440 in FIG. 4A is adopted, only the first terminal of the shunt circuit 440 is coupled to the first terminal of the transmission switch TSW1 and then the two first terminals are jointly coupled to the first chip CH1, and such connection only needs to use one bonding wire, thus reducing a reverse coupling effect caused by using two bonding wires.

Referring to FIG. 4B below, in FIG. 4B, a multi-chip RF circuit 402 includes the amplifying circuits 410 and 430, the transmission circuit 420 and the switch SW2. Where, the amplifying circuits 410 and 430, the transmission circuit 420, and the switch SW2 all have the same coupling relationships and operation details as the components with the same component referential numbers in the embodiment of FIG. 4A, which will not be repeated. Different from the embodiment of FIG. 4A, a shunt circuit 441 in the embodiment includes a reactance element and a switch SW, where the reactance element is, for example, an inductor L3. In the embodiment, the inductor L3 is coupled between the output terminal of the amplifier 432 and the switch SW, and the switch SW is coupled between the inductor L3 and the reference voltage terminal VR2.

In the embodiment, in the low power mode, i.e., the first path P1 is selected, the transmission switches TSW1, TSW3 and the switch SW are all turned on, and the transmission switch TSW2 and the switch SW2 may be turned off, so that the first path P1 may be established. Where, when the switch SW is turned on, the matching circuit 411 and the reactance element (the inductor L3) may provide a high impedance. Furthermore, based on the output terminal of the amplifier 432, the matching circuit 411 has an input impedance (capacitive impedance) of −jx, and the inductor L3 of the shunt circuit 441 may provide an input impedance (inductive impedance) of +jx, where x is any real number. At this time, based on a frequency of the RF signal generated by the amplifier 432, through a resonance effect produced by connecting the capacitive impedance and the inductive impedance in parallel with each other, a relatively high impedance may be generated at an input terminal of the matching circuit 411 to cut off the second path P2.

In the high power mode, i.e., the second path P2 is selected, the transmission switches TSW1, TSW3 and the switch SW are all turned off, and the transmission switches TSW2 and the switch SW2 may be turned on. At this time, the shunt circuit 441 is inactive, the second path P2 may be established, and the first path P1 may be cut off.

It should be noted that in the implementation of FIG. 4A, connection positions of the switch SW and the capacitor C1 in the shunt circuit 440 may be exchanged with each other, as shown in FIG. 4C. Where, in a shunt circuit 443 in a multi-chip RF circuit 403, the switch SW is coupled between the capacitor C1 and the amplifier 432, and the capacitor C1 is coupled between the switch SW and the reference voltage terminal VR2. Similarly, in FIG. 4B, the configuration positions of the inductor L3 and the switch SW in the shunt circuit 441 may also be exchanged with each other. Namely, in an embodiment that is not shown, the switch SW may be coupled between the inductor L3 and the amplifier 432, and the inductor L3 is coupled between the switch SW and the reference voltage terminal VR2.

In addition, in the implementations of FIG. 4A to FIG. 4C, the reference voltage terminals VR1 and VR2 may receive a same reference voltage, or respectively receive different reference voltages. In the embodiment of the disclosure, the reference voltages received by the reference voltage terminals VR1 and VR2 may be smaller than the reference voltage VCC. The reference voltage VCC may be, for example, a supply voltage of the multi-chip RF circuits 200, 300, 401, 402, 403 (and multi-chip RF circuits 500, 600 in subsequent embodiments). The reference voltages received by the reference voltage terminals VR1 and VR2 may be, for example, a ground voltage. Moreover, in the embodiments of FIG. 4A to FIG. 4C, the shunt circuits 440, 441, and 443 may be disposed in the second chip CH2. In other embodiments, for example, when the first chip CH1 adopts a BiFET or a BiCMOS, the shunt circuits 440, 441, and 443 may also be disposed in the first chip CH1.

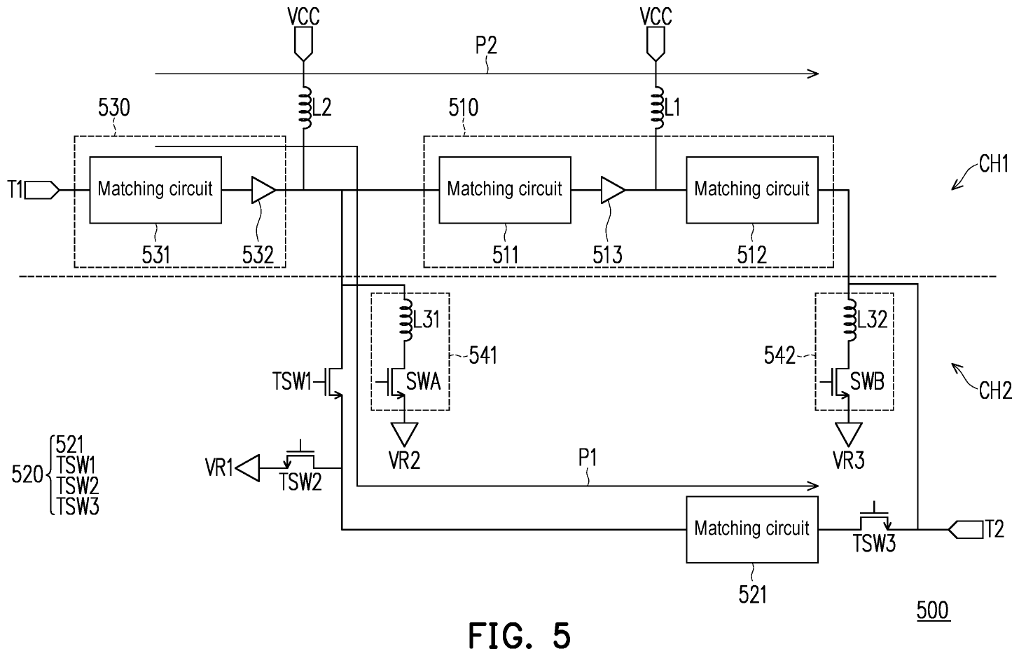

Referring to FIG. 5, FIG. 5 is a schematic diagram of a multi-chip RF circuit according to another embodiment of the disclosure. The multi-chip RF circuit 500 includes amplifying circuits 510 and 530 and a transmission circuit 520. The amplifying circuit 510 includes matching circuits 511 and 512 and an amplifier 513. The amplifying circuit 530 includes a matching circuit 531 and an amplifier 532. The amplifying circuits 510 and 530 are both disposed in the first chip CH1. The transmission circuit 520 includes transmission switches TSW1, TSW2, and TSW3, a matching circuit 521, and shunt circuits 541 and 542. The transmission circuit 520 is disposed in the second chip CH2. The shunt circuit 541 includes a switch SWA and an inductor L31, and the shunt circuit 542 includes a switch SWB and an inductor L32. In the embodiment, the shunt circuits 541 and 542 may be disposed in the second chip CH2. In other embodiments, for example, when the first chip CH1 adopts a BiFET or a BiCMOS, the shunt circuits 541 and 542 may also be disposed in the first chip CH1.

A circuit framework of the embodiment is similar to that of the multi-chip RF circuit 402 of FIG. 4B, and descriptions of the same parts are not repeated. Different from the embodiment of FIG. 4B, the multi-chip RF circuit 500 of the embodiment further includes the shunt circuit 542, where a first terminal of the shunt circuit 542 is coupled between the amplifying circuit 510 and the second port T2. Furthermore, the first terminal of the shunt circuit 542 is coupled between the matching circuit 512 and the second port T2, and the switch SW2 is removed. A second terminal of the shunt circuit 542 is coupled to a reference voltage terminal VR3. The reference voltage terminal VR3 and the reference voltage terminals VR1 and VR2 may receive the same reference voltage, or receive different reference voltages respectively, and the reference voltage received by the reference voltage terminal VR3 may be less than the reference voltage VCC. In addition, the reference voltage received by the reference voltage terminal VR3 may be, for example, a ground voltage. The shunt circuit 542 includes a reactance element and the switch SWB coupled in series. In the embodiment, the reactance element is the inductor L32. Similar to the shunt circuit 441 in the embodiment of FIG. 4B, when the switch SWB is turned on, the matching circuit 512 and the inductor L32 may provide a high impedance. In this way, the shunt circuit 542 may cut off a connection path between the matching circuit 512 and the second port T2. Comparatively, when the switch SWB is turned off, the shunt circuit 542 may turn on the connection path between the matching circuit 512 and the second port T2. In addition, in the embodiment of FIG. 5, the shunt circuit 542 is adopted to replace the switch SW2 of the embodiment of FIG. 3, and when the second path P2 (the high power mode) is selected, the switch SWB in the shunt circuit 542 is turned off; while in the aforementioned embodiment of FIG. 3, when the second path P2 (the high power mode) is selected, the switch SW2 is turned on. In this way, compared with the embodiment of FIG. 3, the embodiment of FIG. 5 requires fewer switching elements to be turned on when the second path P2 (the high power mode) is selected, thereby reducing the insertion loss caused by turning on of the switching elements. In other embodiments that are not shown, the first terminal of the shunt circuit 542 may also be coupled between the amplifier 513 and the matching circuit 512, and the above operations and effects may also be achieved.

In the embodiment, the reactance elements in the shunt circuits 541 and 542 may also be changed to capacitors, and the coupling positions between the reactance elements and the switches SWA and SWB may also be exchanged, as shown in the implementations of FIG. 4A to FIG. 4C. Relevant details have been described in detail in the aforementioned embodiments, which will not be repeated here.

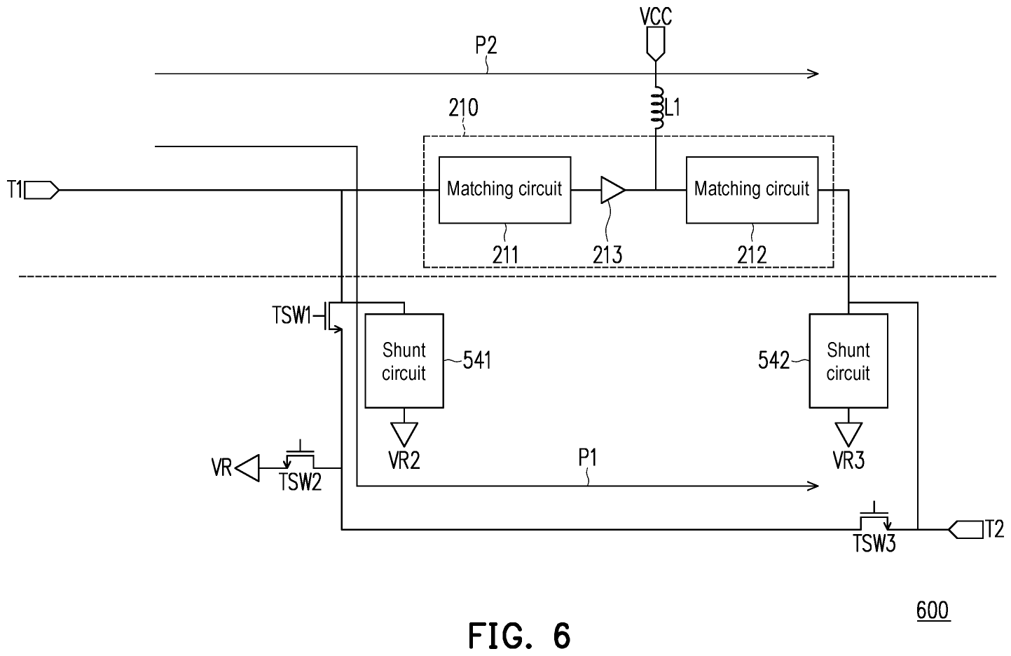

It should be noted that the shunt circuits 541 and 542 of the embodiment may also be applied in a multi-chip RF circuit with only a single amplifying circuit, such as the multi-chip RF circuit 200 in the embodiment of FIG. 2. Referring below to FIG. 6, and FIG. 6 is a schematic diagram of another implementation of a multi-chip RF circuit according to an embodiment of the disclosure. In the multi-chip RF circuit 600, the shunt circuits 541 and 542 may be used to replace the switches SW1 and SW2 respectively. The shunt circuit 541 is coupled between the first port T1 and the reference voltage terminal VR2, the first terminal of the shunt circuit 541 is coupled between the first port T1 and the matching circuit 211, and the first terminal of the shunt circuit 541 is coupled to between the first port T1 and the first terminal of the transmission switch TSW1, the matching circuit 211 is coupled between the first port T1 and the amplifier 213. The first terminal of the transmission switch TSW1 is coupled between the first port T1 and the shunt circuit 541, the first terminal of the shunt circuit 542 may be coupled between the amplifying circuit 210 and the second port T2, and the second terminal of the shunt circuit 542 may be coupled to the reference voltage terminal VR3. Furthermore, the first terminal of the shunt circuit 542 may be coupled between the matching circuit 212 and the second port T2. In other embodiments that are not shown, the first terminal of the shunt circuit 542 may also be coupled between the amplifier 213 and the matching circuit 212.

In the embodiment, operation details of the relevant circuit components have been described in detail in the aforementioned embodiments and implementations, which are not repeated.

In addition, in embodiments that are not shown, the above-mentioned multi-chip RF circuits 100, 200, 300, 401-403, 500, 600 may further include a control circuit for individually providing control signals to the transmission switches TSW, TSW1, TSW2, TSW3 and the switches SW, SW1, SW2, SWA and SWB of the aforementioned embodiments.

In summary, in the disclosure, multiple circuit components of the RF circuit are separately arranged in the first chip and the second chip. Where, the amplifying circuits and the switching elements are respectively arranged in different chips, which may respectively improve the working performance of the amplifying circuits and the switching elements, and at the same time reduce the circuit cost required for the switching elements, and effectively enhance the product competitiveness of the multi-chip RF circuit. In addition, in the embodiments including a shunt circuit, the number of switching elements that need to be turned on may be reduced in the high power mode, thereby reducing the insertion loss caused by turning on of the switching elements.

What is claimed is:

1. A multi-chip radio frequency circuit, coupled between a first port and a second port, the first port being disposed in a first chip, the second port being disposed in a second chip, and the multi-chip radio frequency circuit comprising:
a first amplifying circuit, disposed in the first chip, and coupled to the first port;
a transmission circuit, disposed in the second chip, coupled to the second port, and comprising at least one transmission switch; and
a first switch, coupled to the first amplifying circuit, wherein
the at least one transmission switch and the first switch are configured to select one of a first path and a second path between the first port and second port, and both of the first path and the second path pass through the first chip and second chip, and respectively pass through the transmission circuit and the first amplifying circuit.

2. The multi-chip radio frequency circuit according to claim 1, wherein a material of the first chip comprises gallium arsenide or silicon germanium, and a material of the second chip comprises silicon on insulator.

3. The multi-chip radio frequency circuit according to claim 1, wherein elements of the first chip comprise III-V semiconductors, bipolar field effect transistors, or bipolar complementary metal oxide semiconductors, and elements of the second chip comprise complementary metal oxide semiconductors or pseudomorphic high electron mobility transistors.

4. The multi-chip radio frequency circuit according to claim 1, wherein in a low power mode, the multi-chip radio frequency circuit transmits a radio frequency signal through the first path; in a high power mode, the multi-chip radio frequency circuit transmits the radio frequency signal through the second path.

5. The multi-chip radio frequency circuit according to claim 1, wherein a number of amplifiers passed by the first path is smaller than a number of amplifiers passed by the second path.

6. The multi-chip radio frequency circuit according to claim 1, wherein the first switch is disposed in the second chip.

7. The multi-chip radio frequency circuit according to claim 1, wherein all switches included in the multi-chip radio frequency circuit are disposed in the second chip.

8. The multi-chip radio frequency circuit according to claim 1, wherein the first amplifying circuit comprises a first amplifier, the first switch is coupled between the first port and the first amplifier, when the first path is selected, the first switch is turned off, and when the second path is selected, the first switch is turned on.

9. The multi-chip radio frequency circuit according to claim 8, wherein the at least one transmission switch of the transmission circuit comprises:
a first transmission switch, having a first terminal coupled between the first port and the first switch, and a second terminal coupled to the second port, wherein when the first path is selected, the first transmission switch is turned on, and when the second path is selected, the first transmission switch is turned off.

10. The multi-chip radio frequency circuit according to claim 8 further comprising a second amplifying circuit, wherein the second amplifying circuit further comprises a second amplifier, the second amplifier is coupled between the first port and the first amplifier, and the first switch is further coupled between the second amplifier and the first amplifier.

11. The multi-chip radio frequency circuit according to claim 10, wherein the at least one transmission switch of the transmission circuit comprises:
a first transmission switch, having a first terminal coupled between the second amplifier and the first switch, and a second terminal coupled to the second port, wherein when the first path is selected, the first transmission switch is turned on, and when the second path is selected, the first transmission switch is turned off.

12. The multi-chip radio frequency circuit according to claim 1 further comprising a first shunt circuit, wherein the first shunt circuit comprises a first reactance element, the first reactance element is a first capacitor or a first inductor, a first terminal of the first shunt circuit is coupled to the first amplifying circuit, and a second terminal of the first shunt circuit is coupled to a reference voltage terminal.

13. The multi-chip radio frequency circuit according to claim 12, wherein the first shunt circuit further comprises the first switch, and the first switch is coupled between the first reactance element and the reference voltage terminal, or the first reactance element is coupled between the first switch and the reference voltage terminal.

14. The multi-chip radio frequency circuit according to claim 13, wherein the first amplifying circuit comprises a first amplifier and a first matching circuit, the first matching circuit is coupled between the first port and the first amplifier, the first terminal of the first shunt circuit is coupled between the first port and the first matching circuit, when the first path is selected, the first switch is turned on, and the first matching circuit and the first reactance element provide a high impedance, and when the second path is selected, the first switch is turned off.

15. The multi-chip radio frequency circuit according to claim 14, wherein the at least one transmission switch of the transmission circuit comprises:
a first transmission switch, having a first terminal coupled between the first port and the first shunt circuit, and a second terminal coupled to the second port, wherein when the first path is selected, the first transmission switch is turned on, and when the second path is selected, the first transmission switch is turned off.

16. The multi-chip radio frequency circuit according to claim 13 further comprising a second amplifying circuit, wherein the first amplifying circuit comprises a first amplifier and a first matching circuit, the second amplifying circuit comprises a second amplifier, the second amplifier is coupled between the first port and the first amplifier, the first matching circuit is coupled between the second amplifier and the first amplifier, the first terminal of the first shunt circuit is coupled between the second amplifier and the first matching circuit, when the first path is selected, the first switch is turned on, the first matching circuit and the first reactance element provide a high impedance, and when the second path is selected, the first switch is turned off.

17. The multi-chip radio frequency circuit according to claim 16, wherein the at least one transmission switch of the transmission circuit further comprises:
a first transmission switch, having a first terminal coupled between the second amplifier and the first shunt circuit, and a second terminal coupled to the second port, wherein when the first path is selected, the first transmission switch is turned on, and when the second path is selected, the first transmission switch is turned off.

18. The multi-chip radio frequency circuit according to claim 12 further comprising a second shunt circuit, wherein the second shunt circuit comprises a second reactance element, the second reactance element is a second capacitor or a second inductor, a first terminal of the second shunt circuit is coupled between the first amplifying circuit and the second port, and a second terminal of the second shunt circuit is coupled to the reference voltage terminal.

19. The multi-chip radio frequency circuit according to claim 18 further comprising a second switch, wherein the second switch is located in the second shunt circuit, and the second switch is coupled between the second reactance element and the reference voltage terminal, or the second reactance element is coupled between the second switch and the reference voltage terminal.

20. The multi-chip radio frequency circuit according to claim 19, wherein the first amplifying circuit comprises a first amplifier and a second matching circuit, the second matching circuit is coupled between the first amplifier and the second port, the first terminal of the second shunt circuit is coupled between the first amplifier and the second matching circuit or between the second matching circuit and the second port, when the first path is selected, the second switch is turned on, and the second matching circuit and the second reactance element provide a high impedance, and when the second path is selected, the second switch is turned off.
